(19) United States
(12) Patent Application Publication
(10) Pub. No.: US 2007/0097607 A1
(43) Pub. Date: May 3, 2007

(54) Sliding mechanism with variable sliding range thereof

(75) Inventor: Chung-Han Lee, Taipei (TW)

Correspondence Address: LADAS & PARRY, 26 WEST 61ST STREET, NEW YORK, NY, 10023, US

(73) Assignee: BENQ CORPORATION

(21) Appl. No.: 11/520,434

(22) Filed: Sep. 13, 2006

(30) Foreign Application Priority Data
Sep. 13, 2005 (TW) 94131549

(51) Int. Cl. H05K 5/00

(52) U.S. Cl. 361/679; 361/600

(57) ABSTRACT

A sliding mechanism with variable sliding range thereof is disclosed, which is applied to a sliding type mobile phone and comprises: a slider; two sliding blocks for sliding on the slider and each having a sliding groove thereon; two rods, each having a fixed end and a free end, wherein the fixed ends are mounted on the slider, and the free ends are respectively located in the sliding grooves of the two sliding blocks; and two springs, respectively located in the sliding grooves of the two sliding blocks and connected the free ends of the two rods; whereby when the distance between the two sliding blocks is increased, the sliding range of the two sliding blocks is increased.

### BACKGROUND OF THE INVENTION

(1) Field of the Invention

The invention relates to a sliding mechanism with variable sliding range thereof, and more particularly to a sliding mechanism applied to a sliding type mobile phone.

(2) Description of the Prior Art

Recently, the designs of modem mobile phones have become more complex, and now, the sliding type mobile phone is the mainstream in the mobile phone industry.

The most important part of the sliding type mobile phone is the cover-sliding structure. In order to open the sliding cover easily, the design of the most sliding cover is semi-automatic. That is, user pushes the sliding cover for a certain distance, the sliding cover may reach an open position or a closed position thereof.

Please refer to FIG. 1A, which illustrates a sliding type mobile phone with a cover-sliding structure in the prior art. As shown in FIG. 1A, the cover-sliding structure 10 includes a slider 12, a sliding block 14, a rod 16, an expansion spring 18, and a torsional spring 19, wherein the sliding block 14 is installed on the slider 12. On the sliding block 14, there is a sliding groove 142. The moving direction of the sliding groove 142 is perpendicular to the moving direction of the slider 12. The rod 16 has a fixed end 162 and a free end 164, wherein the fixed end is mounted on the slider 12, and the free end 164 slides in the sliding groove 142. The expansion spring 18 is in the sliding groove 142. One end of the expansion spring 18 is connected to an end of the sliding groove 142, and the other end of the expansion spring 18 is connected to the free end 164. Both ends of the torsion spring 19 are respectively connected to the slider 12 and the sliding block 14.

FIG. 1A, FIG. 1B, and FIG. 1C illustrate the sliding process of the cover-sliding structure. As shown in the figures, the movement of the sliding block 14 can also make the rod 16 rotate, so that the free end 164 of the rod 16 can move along the sliding groove 142. However, according to the design of the sliding groove 142, the free end 164 of the rod 16 can only slides in a certain range of the sliding groove. In other words, the rod 16 can only rotate in the certain range as shown in FIG. 1A to 1C, and thus, the sliding block 14 is limited to slide in a certain range. The range is the sliding range of the cover-sliding structure.

Again, when the sliding block 14 moves from a position shown in FIG. 1A to a position shown in FIG. 1B, the expansion spring 18 in the sliding groove 142 is expanded, so that an elastic restoration force is produced, which is applied to the free end 164 of the rod 16. The elastic restoration force makes the length of the expansion spring 18 be shrunk back to the length as shown in FIG. 1A and FIG. 1C. That is, the elastic restoration force provided by the torsion spring 18 make the sliding block 14 move toward an end point of its sliding travel, as shown in FIG. 1A and FIG. 1C.

Next, the movement of the sliding block can also change the torsion extent of the torsional spring 19. The main purpose of the torsional spring 19 is to appropriately balance a force exerted by the expansion spring 18, so that the sliding block 14 can move more stably. Furthermore, if the torsional spring 19 in FIG. 1B is in its original status, then the force provided by the torsional spring 19 make the sliding block 14 to move toward the center of the sliding range, as shown in FIG. 1B. Therefore, the force provided by the torsional spring 19 may partially counterbalance the force provided by the expansion spring 18, specially, at the ends of the sliding travel of the sliding block, as shown in FIG. 1A and FIG. 1C, and vibration caused by the sliding block 14 during sliding process can be greatly reduced.

However, the sliding range of the cover-sliding structure 10 cannot be changed due to its structural design; therefore, in order to match different mobile phones with sliding covers, it is necessary to develop various sliding mechanisms having different sliding ranges, which means that not only the costs of design and production are increased, but also raw materials to be used are increased.

In view of the above-mentioned problems, the present invention provides a sliding mechanism with variable sliding range thereof, which can match, through changing the sliding range, with mobile phones having different sliding covers, so that production costs can be saved, and the raw materials to be used can be reduced.

### SUMMARY OF THE INVENTION

It is an object of the present invention to provide a sliding mechanism with variable sliding range thereof so as to match mobile phones having different sliding covers.

The present invention provides a sliding mechanism with variable sliding range thereoffor use on a sliding type mobile phone. The sliding mechanism with variable sliding range thereof includes a slider, two sliding blocks, two rods, and two springs, wherein the two sliding block slide on the slider, the distance between the two sliding blocks is adjustable. Moreover, each sliding blocks has a sliding groove thereon. Each rod has a fixed end and a free end. The fixed ends are mounted on the slider, and the free ends are respectively located in the sliding grooves of these two sliding blocks. These two springs are located in the sliding groove of these two sliding blocks, and are respectively connected to the free ends of the correspondent rods. Thereby, when the distance between the two sliding blocks is increased, the sliding range of the sliding blocks on the slider can be increased as well.

Through the sliding mechanism with its variable sliding range of the present invention, the present invention also provides a sliding type mobile phone. The sliding type mobile phone has an upper body, a lower body, and a sliding mechanism, wherein the sliding mechanism includes a slider, two sliding blocks, two rods, and two springs. The slider is mounted on the lower body. The two sliding blocks are mounted on the upper body and can slide on the slider. The distance between the sliding blocks is adjustable. Moreover, each sliding block has a sliding groove thereon. Each rod has a fixed end and a free end. The fixed ends are mounted on the slider and the free ends of the two rods are respectively located in the sliding grooves of the correspondent sliding blocks. The two springs are respectively located in the sliding grooves of the sliding blocks, and are respectively connected to the free ends of the correspondent rods. Thereby, when the distance between the two sliding blocks is increased, the sliding travel of the upper body in response to the lower body is also increased.

### BRIEF DESCRIPTION OF THE DRAWINGS

The present invention will now be specified with reference to its preferred embodiment illustrated in the drawings, in which:

FIG. 1A to FIG. 1C illustrate a sliding mechanism and its sliding process of a sliding type mobile phone in the prior art;

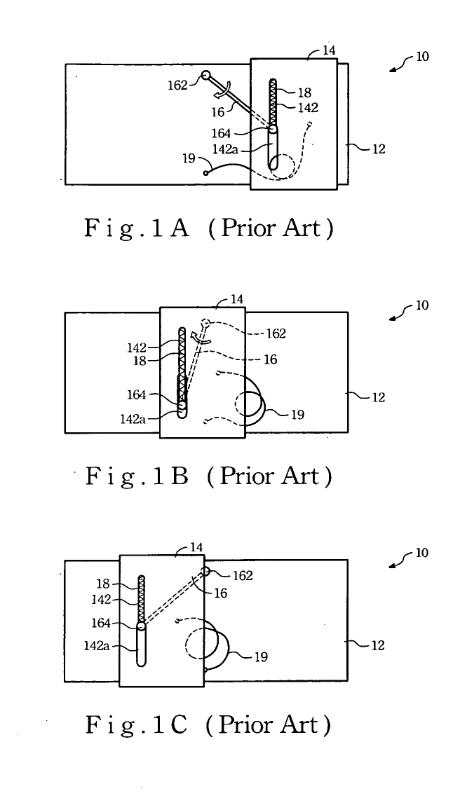

FIG. 2A to FIG. 2C illustrate a sliding mechanism with its variable sliding range and its sliding process of the present invention;

FIG. 3 is an enlarged view of sliding blocks of a preferred embodiment of the present invention;

FIG. 4 to FIG. 5 illustrate that adjusting the distance between the first sliding block and the second sliding block to change the sliding range; and

FIG. 6A and FIG. 6B illustrate the sliding mechanism with variable sliding range of the present invention, which is applied to a sliding type mobile phone.

### DESCRIPTION OF THE PREFERRED EMBODIMENTS

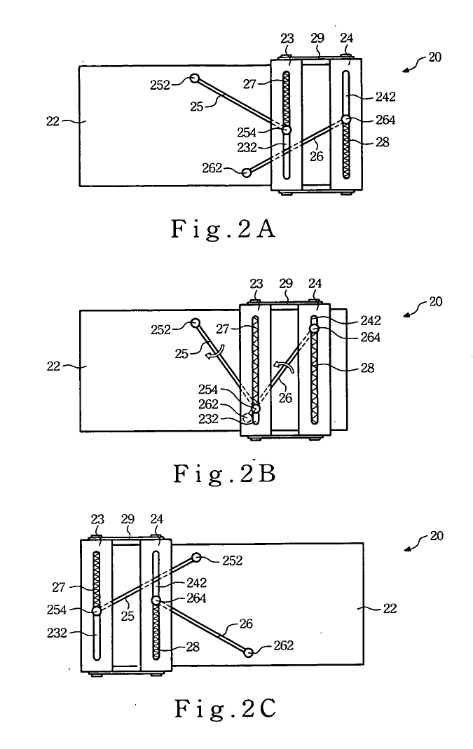

Please refer to FIG. 2A, which illustrates a sliding mechanism with variable sliding range of a sliding type mobile phone of the present invention. As shown in the figure, the sliding mechanism 20 includes a slider 22, a first sliding block 23, a second sliding block 24, two pieces of plates 29, a first rod 25, a second rod 26, a first spring 27, and a second spring 28. The first sliding block 23 and the second sliding block 24 slide on the slider 22. The two plates 29 are mounted at ends of the first sliding block 23 and the second sliding block 24 so as to determine the distance between the first sliding block 23 and the second sliding block 24.

The first sliding block 23 has a first sliding groove 232 thereon, and the second sliding block 24 has a second sliding groove 242 thereon. The first sliding groove 232 is perpendicular to the slider 22, and the second sliding groove 242 is perpendicular to the slider 22. The first rod 25 has a first fixed end 252 and a first free end 254. The first fixed end 252 is mounted on the slider 22, and the first free end 254 is located in the first sliding groove 232. The second rod 26 has a second fixed end 262 and a second free end 264. The second fixed end 262 is mounted on the slider 22, and the second free end 264 is located in the second sliding groove 242.

The first spring 27 is located in the first sliding groove 232. An end (top end as shown in the figure) of the first spring 27 is mounted on the first sliding block 23, and another end of the first spring 27 is connected to the first free end 254. The second spring 28 is located in the second sliding groove 242. An end (bottom end as shown in the figure) of the second spring 28 is mounted on the second sliding block 24, and the other end of the second spring 28 is connected to the second free end 264.

Please refer to FIG. 2A to FIG. 2C, which illustrate the sliding process of the sliding mechanism 20 of the present invention. As shown in the figures, because the first fixed end 252 and the second fixed end 262 are respectively close to the ends of the slider 22, and the first sliding block 23 and the second sliding block 24 slides from the right-hand end to the left-hand end, the movement of first sliding block 23 on the slider 22 makes the first rod 25 to rotate in a clockwise direction, indicated by an arrow as shown in FIG. 2B. The movement of the second sliding block 24 on the slider 22 makes the second rod 26 to rotate in a counterclockwise direction, indicated by an arrow, as shown in FIG. 2B. Simultaneously, the rotations of the first rod 25 and the second rod 26 also make the first free end 254 and the second free end 264 to slide along the first sliding groove 232 and the second sliding groove 242.

As shown in FIGS. 2A and 2B, when the first sliding block 23 and the second sliding block 24 move from the right-hand end to the center of the slider 22, the first free end 254 slides down along the first sliding groove 232, and the second free end 264 slides up along the second sliding groove 242. At the same time, the first spring 27 is stretched to produce an elastic restoration force which is applied to the first free end 254, and the second spring 28 is stretched to produce an elastic restoration force which is applied to the second free end 264. Please refer to FIG. 2B to 2C, when the first sliding block 23 and the second sliding block 24 move from the center to the left-hand end of the slider 22, the first spring 27 and the second spring 28 gradually recover to its original length, as shown in FIG. 2C. Therefore, as the first spring 27 and the second spring 28 are stretched by an external force, the elastic restoration force is produced and making the first sliding block 23 and the second sliding block 25 to move toward the left-hand end and the right-hand end of the slider 22, as shown in FIG. 2A and FIG. 2C.

it must be noted that the first fixed end 242 is located in the sliding range of the sliding groove 22 of the first sliding block 23, and the second fixed end 262 is located in the sliding range of the sliding groove 22 of the second sliding block 24. In other words, as the first sliding block 23 moves, the first free end 254 moves from one side to the other side of the fixed end 252. As the second sliding block 24 moves, the second free end 264 moves from on side to the other side of the second fixed end 262. During the movement, there is a balance position where the force applied to the first sliding block 23 by the first spring 27 counterbalances the force applied to the second sliding block 23 by the second spring 28. When the two sliding blocks 23 and sliding blocks 24 depart from the balance positions, the forces provided by the two springs 27 and 28 make the sliding blocks 23 and 24 to move toward the left-hand end and right-hand end of the slider 22.

In the preferred embodiment of the present invention, the first spring 27 and the second spring 28 can be two torsional springs. Under the conditions as shown in FIG. 2A and FIG. 2C, the first spring 27 and the second spring 28 are in an unexpanded status;, when the first sliding block 23 and the second sliding block 24 are sliding along the slider 22 as shown in FIG. 2B, the first spring 27 and the second spring 28 are in an expanded status.

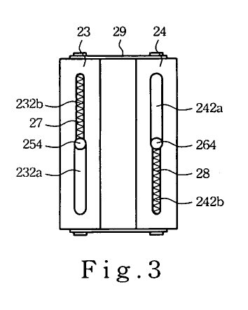

Please refer to FIG. 3, which is an enlarged view of the sliding blocks 23 and 24. Taking the first sliding block as an example, the first sliding groove of the first sliding block 23 is divided into an upper portion and a lower portion, wherein the width of the upper portion 232b is smaller than that of the lower portion 232a, so the free end 254 of the first rod can only slide in the lower portion 232a of the first sliding groove. In other words, the upper end of the lower portion limits the sliding range of the free end 254. Similarly, the lower end of the upper portion 242a of the second sliding groove limits the sliding range of the free end 264.

As mentioned above, since the free ends 254 and 264 of the first rod and the second free end are limited, the first rod 25 and the second rod 26 can only slide in a certain range in the first sliding groove 232 and the second sliding groove 242. Therefore, the rotating ranges of the first rod 25 and the second rod 26 are limited and can only rotate in a certain range as shown in FIG. 2A and FIG. 2C, and the sliding ranges of the first sliding block 23 and the second sliding block 24 are also limited and can only slide in a certain range. The certain range means the sliding range of the sliding mechanism 20.

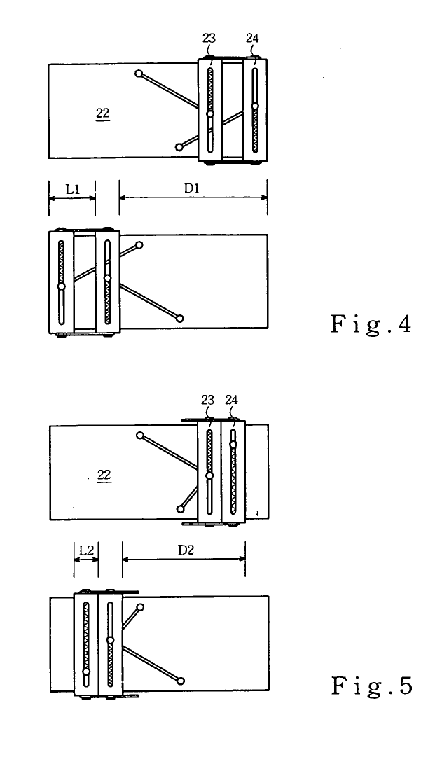

Please refer to FIG. 4 and FIG. 5, which show the effect of changing the distance between the first sliding block 23 and the second sliding block 24 on the sliding range of the slider. As shown in the figures, when the distance between the first sliding block 23 and the second sliding block 24 is reduced from L1 to L2, the sliding range of the first sliding block 23 and the second sliding block 24 is reduced from D1 to D2.

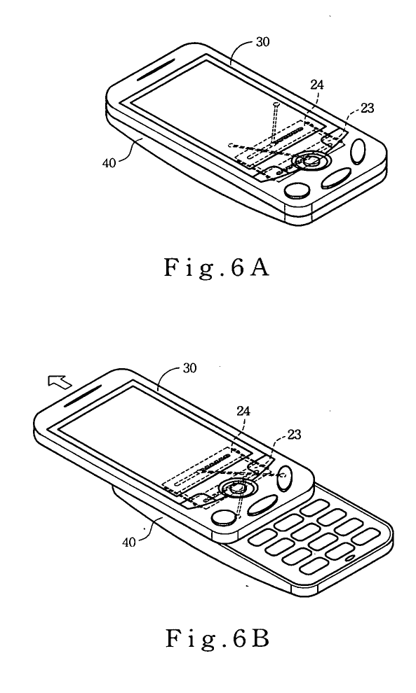

Please refer to FIGS. 6A and 6B, which show the preferred embodiment, in which the sliding mechanism with its variable sliding range is applied to the sliding type mobile phone. As shown in the figures, the sliding type mobile phone has an upper body 30, a lower body 40. The slider 22 is disposed on the lower body 40. The two sliding blocks 23 and 24 are mounted on the upper body 30 and slide on the slider 22. Thereby, the upper body 30 of the sliding type mobile phone can slide relative to the lower body 40. Basically, the upper body 30 can be the sliding cover of the sliding type mobile phone, and the lower body can be provided with a printed circuit board, a battery, and touch panel elements etc.

As shown in FIG. 4 and FIG. 5, adjusting the distance between the first sliding block 23 and the second sliding block 24 can change the sliding range of the sliding mechanism of the present invention; moreover, the distance between the first sliding block 23 and the second sliding block 24 can be determined through changing the position where they are mounted on the plates 29. Therefore, the sliding mechanism of the present invention can match with different sliding type mobile phones through adjusting its sliding range. Thereby, the design and production costs can be reduced, and the raw materials to be used can be reduced also.

While the present invention has been particularly shown and described with reference to a preferred embodiment, it will be understood by those skilled in the art that various changes in form and detail may be without departing from the spirit and scope of the present invention.

I claim:

1. A sliding mechanism with variable sliding range for use on a sliding type mobile phone, comprising:
a slider;
a first sliding block which slides on the slider and has a first sliding groove;
a second sliding block which slides on the slider and has a second sliding groove;
a plate connecting to the first sliding block and the second sliding block for determining the distance between the first sliding block and the second sliding block;
a first rod having a first fixed end and a first free end, wherein the first fixed end is mounted on the slider and the first free end is located in the first sliding groove, when the first sliding block slides along the slider, the first free end slides along the first sliding groove;
a second rod having a second fixed end and a second free end, wherein the second fixed end is mounted on the slider and the second free end is located in the second sliding groove, when the second sliding block slides along the slider, the second free end slides along the second sliding groove;
a first spring, located in the first sliding groove, having an end of the first spring mounted on the first sliding block and another end of the first spring connected to the first free end; and
a second spring, located in the second sliding groove, having an end of the second spring mounted on the second sliding block and the other end of the second spring connected to the second free end;
whereby when the distance between the first sliding block and the second sliding block is increased, the sliding range of the first sliding block and the second sliding block on the slider is increased.

2. The mechanism according to claim 1, wherein the first sliding groove is perpendicular to the slider.

3. The mechanism according to claim 2, wherein the second sliding groove is perpendicular to the sliding groove.

4. The mechanism according to claim 1, wherein the first fixed end and the second fixed end are located on opposite sides of the slider.

5. The mechanism according to claim 4, wherein when the first sliding block and the second sliding block slide on the slider, the first rod and the second rod respectively rotate in a clockwise direction and in a counterclockwise direction.

6. The mechanism according to claim 1, wherein the first fixed end is within the sliding range of the first sliding block.

7. The mechanism according to claim 6, wherein the second fixed end is located in the sliding range of the second sliding block.

8. The mechanism according to claim 1, wherein the first spring is an expansion spring, and in the sliding range of the first sliding block, the first spring is in an expanded status.

9. The mechanism according to claim 8, wherein the second spring is an expansion spring, and in the sliding range of the second sliding block, the second spring is in an expanded status.

10. A sliding mechanism with variable sliding range for use on a sliding type mobile phone, comprising:
a slider;
two sliding blocks for sliding on the slider, each having a sliding groove thereon, wherein the distance between the two sliding blocks is adjustable;
two rods, each having a fixed end and a free end, wherein the fixed ends are mounted on the slider and the free ends are respectively located in the sliding grooves of the two sliding blocks; and
two springs, respectively located in the sliding grooves of the two sliding blocks and respectively connected to the free ends of the two rods;
whereby when the distance between the two sliding blocks is increased, the sliding range of the two sliding blocks is increased.

11. The mechanism according to claim 10, wherein the two sliding grooves are perpendicular to the slider.

12. The mechanism according to claim 10, wherein when the two sliding blocks move along the slider, the two rods respectively rotate in a clockwise direction and in a counterclockwise direction.

13. The mechanism according to claim 10, wherein the fixed ends of the two rods are located within the sliding range of the two sliding blocks.

14. The mechanism according to claim 10, wherein the fixed ends of the two rods are located on opposite sides of the slider.

15. The mechanism according to claim 10, wherein the sliding range has a balance position, and when the two sliding blocks move to the balance position, forces provided to the two sliding blocks by the two springs counterbalance each other.

16. The mechanism according to claim 15, wherein when the two sliding blocks depart from the balance position, the forces provided by the two springs make the two sliding blocks depart from the balance position.

17. The mechanism according to claim 10, wherein the two springs are expansion springs, and in the sliding ranges of the two sliding blocks, the two springs are in an expanded status.

18. A sliding type mobile phone having an upper body, a lower body, and a sliding mechanism, wherein the sliding mechanism comprises:
a slider mounted on the lower body;
two sliding blocks, mounted on the upper body for sliding on the slider, wherein the distance between the two sliding blocks is adjustable, and each of the sliding blocks has a sliding groove thereon;
two rods, each having a fixed end and a free end, wherein the fixed ends are mounted on the slider, and the free ends of the two rods are respectively located in the sliding grooves of the two sliding blocks; and
two springs, respectively located in the sliding grooves of the two sliding blocks and respectively connected to the free ends of the two rods;
whereby when the distance between the two sliding blocks is increased, the sliding range of the upper body relative to the lower body is increased.

19. The mechanism according to claim 18, wherein the two sliding grooves are perpendicular to the slider.

20. The mechanism according to claim 18, wherein when the two sliding blocks slide along the slider, the two rods respectively rotate in a clockwise direction and in a counterclockwise direction.
